(19) United States
(12) Patent Application Publication
(10) Pub. No.: US 2025/0226639 A1
(43) Pub. Date: Jul. 10, 2025

(54) SURFACE EMITTING LASER, SURFACE EMITTING LASER ARRAY, AND ELECTRONIC DEVICE

(71) Applicant: SONY GROUP CORPORATION, TOKYO (JP)

(72) Inventors: EIJI NAKAYAMA, TOKYO (JP); KENTARO HAYASHI, TOKYO (JP); TATSUSHI HAMAGUCHI, TOKYO (JP); RINTARO KODA, TOKYO (JP)

(21) Appl. No.: 18/847,576

(22) PCT Filed: Feb. 15, 2023
(86) PCT No.: PCT/JP2023/005214

§ 371 Date: Sep. 16, 2024

(30) Foreign Application Priority Data
Mar. 24, 2022 (JP) 2022-047753

(51) Int. Cl. H01S 5/042; H01S 5/183; H01S 5/323; H01S 5/42

(52) U.S. Cl. CPC H01S 5/04254; H01S 5/18361; H01S 5/18386; H01S 5/32308; H01S 5/423

(57) ABSTRACT

To provide a surface emitting laser, a surface emitting laser array, and an electronic device that improve the reliability of a transparent conductive film.

The present technique provides a surface emitting laser including: a first structure including a first multilayer reflective mirror; an active layer; and a second structure including a transparent conductive film, a pad electrode, and a second multilayer reflective mirror, the first structure, the active layer, and the second structure being disposed in this order, in which a film thickness of the transparent conductive film disposed at a position in contact with the pad electrode is greater than a film thickness of the transparent conductive film disposed on an optical path of light generated by the active layer.

### TECHNICAL FIELD

The technique (hereinafter also called “present technique”) related to the present disclosure relates to a surface emitting laser, a surface emitting laser array, and an electronic device.

### BACKGROUND ART

There have conventionally been used surface emitting lasers (VCSELs: Vertical Cavity Surface Emitting Lasers) that emit light in a direction perpendicular to a semiconductor substrate. The surface emitting lasers are used in a wide variety of fields such as optical communication, optoelectronic devices, and optical sensing, for example.

A transparent conductive film (a film made of a material having conductivity and optical transparency) to which a current from a pad electrode is input is used in the surface emitting lasers, as disclosed in PTL 1, etc., for example.

### CITATION LIST

### Patent Literature

### [PTL 1]

JP 2007-059672A

### SUMMARY

### Technical Problem

However, there is room for improvement in the reliability of the transparent conductive film.

Thus, a main object of the present technique is to provide a surface emitting laser, a surface emitting laser array, and an electronic device that improve the reliability of a transparent conductive film.

### Solution to Problem

The present technique provides a surface emitting laser including: a first structure including a first multilayer reflective mirror; an active layer; and a second structure including a transparent conductive film, a pad electrode, and a second multilayer reflective mirror, the first structure, the active layer, and the second structure being disposed in this order, in which a film thickness of the transparent conductive film disposed at a position in contact with the pad electrode is greater than a film thickness of the transparent conductive film disposed on an optical path of light generated by the active layer.

The film thickness of the transparent conductive film disposed at a position in contact with the pad electrode may be 1.5 times or more the film thickness of the transparent conductive film disposed on the optical path of the light generated by the active layer.

The film thickness of the transparent conductive film disposed at a position in contact with the pad electrode may be twice or more the film thickness of the transparent conductive film disposed on the optical path of the light generated by the active layer.

The transparent conductive film may be formed such that the film thickness of the transparent conductive film becomes greater from the optical path of the light generated by the active layer toward the pad electrode.

The transparent conductive film may be formed in a tapered shape.

The transparent conductive film may be formed in a staircase shape including at least one step.

The step may be formed outside a resonator disposed between the first multilayer reflective mirror and the second multilayer reflective mirror.

The step may be formed inside a resonator disposed between the first multilayer reflective mirror and the second multilayer reflective mirror.

The step may be formed inside a current injected region.

The step may be formed outside a current injected region; and the film thickness of the transparent conductive film disposed on an optical path axis of the light generated by the active layer may be greater than the film thickness of the transparent conductive film disposed in regions other than that on the optical path.

The transparent conductive film may be formed such that the film thickness of the transparent conductive film becomes smaller from the optical path of the light generated by the active layer toward the pad electrode.

The transparent conductive film may be formed in a tapered shape.

The transparent conductive film may include a plurality of film qualities.

The transparent conductive film disposed at a position in contact with the pad electrode may include a film quality with a lower electric resistance than that of the transparent conductive film disposed on the optical path of the light generated by the active layer.

A resonator disposed between the first multilayer reflective mirror and the second multilayer reflective mirror may contain a III-V compound.

The resonator may contain one or more kinds of compounds selected from the group consisting of AlGaInN, AlGaInP, AlGaAs, and AlGaInNAs.

The surface emitting laser may further include light converging-diverging means for converging or diverging the light generated by the active layer.

The surface emitting laser may be constituted as a mesa-type structure.

The present technique also provides a surface emitting laser array including the surface emitting lasers arranged multi-dimensionally.

The present technique also provides an electronic device including the surface emitting laser.

According to the present technique, it is possible to provide a surface emitting laser, a surface emitting laser array, and an electronic device that improve the reliability of a transparent conductive film. The effects described here are not necessarily limited and may be any of the effects described in the present disclosure.

### BRIEF DESCRIPTION OF DRAWINGS

FIG. 1 is a cross-sectional view illustrating a configuration example of a surface emitting laser 1 according to one embodiment of the present technique.

FIG. 2 is a cross-sectional view illustrating a configuration example of the surface emitting laser 1 according to one embodiment of the present technique.

FIG. 3 is a cross-sectional view illustrating a configuration example of the surface emitting laser 1 according to one embodiment of the present technique.

FIG. 4 is a cross-sectional view illustrating a configuration example of the surface emitting laser 1 according to one embodiment of the present technique.

FIG. 5 is a cross-sectional view illustrating a configuration example of the surface emitting laser 1 according to one embodiment of the present technique.

FIG. 6 is a cross-sectional view illustrating a configuration example of the surface emitting laser 1 according to one embodiment of the present technique.

FIG. 7 is a cross-sectional view illustrating a configuration example of the surface emitting laser 1 according to one embodiment of the present technique.

FIG. 8 is a cross-sectional view illustrating a configuration example of the surface emitting laser 1 according to one embodiment of the present technique.

FIG. 9 is a cross-sectional view illustrating a configuration example of the surface emitting laser 1 according to one embodiment of the present technique.

FIG. 10 is a cross-sectional view illustrating a configuration example of the surface emitting laser 1 according to one embodiment of the present technique.

FIG. 11 is a cross-sectional view illustrating a configuration example of the surface emitting laser 1 according to one embodiment of the present technique.

FIG. 12 is a cross-sectional view illustrating a configuration example of the surface emitting laser 1 according to one embodiment of the present technique.

FIG. 13 is a perspective view illustrating a configuration example of a surface emitting laser array 100 according to one embodiment of the present technique.

FIG. 14 is a cross-sectional view illustrating a configuration example of the surface emitting laser 1 according to one embodiment of the present technique.

FIG. 15 is a cross-sectional view illustrating a configuration example of the surface emitting laser 1 according to one embodiment of the present technique.

FIG. 16 is a cross-sectional view illustrating a configuration example of the surface emitting laser 1 according to one embodiment of the present technique.

FIG. 17 is a cross-sectional view illustrating a configuration example of the surface emitting laser 1 according to one embodiment of the present technique.

FIG. 18 is a cross-sectional view illustrating a configuration example of the surface emitting laser 1 according to one embodiment of the present technique.

FIG. 19 is a cross-sectional view illustrating a configuration example of the surface emitting laser 1 according to one embodiment of the present technique.

FIG. 20 is a cross-sectional view illustrating a configuration example of the surface emitting laser 1 according to one embodiment of the present technique.

FIG. 21 is a cross-sectional view illustrating a configuration example of the surface emitting laser 1 according to one embodiment of the present technique.

### DESCRIPTION OF EMBODIMENT

The following is a description of preferable embodiments for implementing the present technique with reference to the drawings. The embodiments which will be described below show an example of representative embodiments of the present technique, and the scope of the present technique should not be limited on the basis of these embodiments. Furthermore, any of the following Examples and modifications thereof may be combined in the present technique.

In the description of the embodiments below, configurations may be described using terms with “substantially”, such as substantially parallel or substantially orthogonal. For example, the term “substantially parallel” means not only fully parallel but also practically parallel; that is, the term includes a state that deviates from a completely parallel state by, for example, a few percent. The same applies to other terms with “substantially”. Furthermore, the drawings are schematic diagrams and are not necessarily exact illustrations. The drawings are emphatically scaled to facilitate understanding of the features of the technique. It should be noted that the scale of the drawings does not necessarily match the scale of the actual device to that end.

In the drawings, unless otherwise specified, “up” means the upper direction or the upper side in the drawing, “down” means the lower direction or the lower side in the drawing, “left” means the left direction or the left side in the drawing, and “right” means the right direction or the right side in the drawing. Also, the same reference signs will be given to the same or equivalent elements or members in the drawings, and redundant descriptions thereof will not be given.

Description will be given in the following order. 1. First Embodiment of Present Technique (Example 1 of Surface Emitting Laser)
(1) Overall Configuration
(2) Multilayer Reflective Mirror
(3) Compound Semiconductor Substrate
(4) Laminated Structure
(5) Transparent Conductive Film
2. Second Embodiment of Present Technique (Example 2 of Surface Emitting Laser)
3. Third Embodiment of Present Technique (Example 3 of Surface Emitting Laser)
4. Fourth Embodiment of Present Technique (Example 4 of Surface Emitting Laser)
5. Fifth Embodiment of Present Technique (Example 5 of Surface Emitting Laser)
6. Sixth Embodiment of Present Technique (Example 6 of Surface Emitting Laser)
7. Seventh Embodiment of Present Technique (Example 7 of Surface Emitting Laser)
8. Eighth Embodiment of Present Technique (Example 8 of Surface Emitting Laser)
9. Ninth Embodiment of Present Technique (Example 9 of Surface Emitting Laser)
10. Tenth Embodiment of Present Technique (Example 10 of Surface Emitting Laser)
11. Eleventh Embodiment of Present Technique (Example 11 of Surface Emitting Laser)
12. Twelfth Embodiment of Present Technique (Example 12 of Surface Emitting Laser)
13. Thirteenth Embodiment of Present Technique (Example of Electronic Device)
14. Fourteenth Embodiment of Present Technique (Example of Method of Producing Surface Emitting Laser)

### 1. First Embodiment of Present Technique (Example 1 of Surface Emitting Laser)

### [(1) Overall Configuration]

The present technique provides a surface emitting laser including: a first structure including a first multilayer reflective mirror; an active layer; and a second structure including a transparent conductive film, a pad electrode, and a second multilayer reflective mirror, the first structure, the active layer, and the second structure being disposed in this order, in which a film thickness of the transparent conductive film disposed at a position in contact with the pad electrode is greater than a film thickness of the transparent conductive film disposed on an optical path of light generated by the active layer.

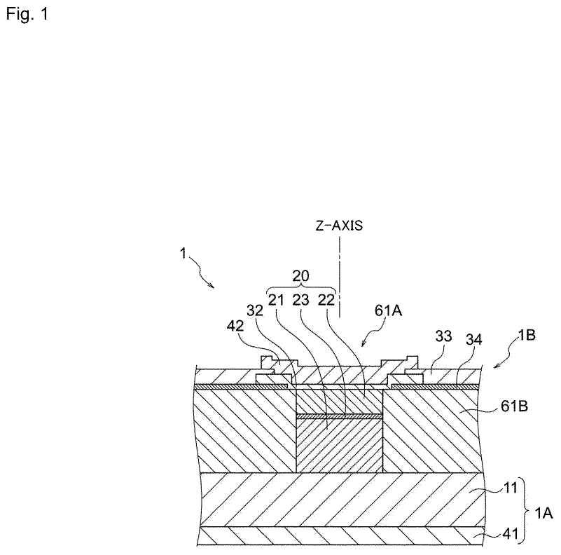

A configuration example of a surface emitting laser according to one embodiment of the present technique will be described with reference to FIG. 1. FIG. 1 is a cross-sectional view illustrating a configuration example of a surface emitting laser 1 according to one embodiment of the present technique. As illustrated in FIG. 1, a first structure 1A, an active layer 23, and a second structure 1B are disposed in this order.

The first structure 1A includes a first multilayer reflective mirror 41. The first multilayer reflective mirror 41, a compound semiconductor substrate 11, and a first compound semiconductor layer 21 are disposed in this order.

The second structure 1B includes a transparent conductive film 32, a pad electrode 33, and a second multilayer reflective mirror 42. The transparent conductive film 32 is disposed on the second compound semiconductor layer 22. The pad electrode 33 is formed on or connected to an edge portion of the transparent conductive film 32. The second multilayer reflective mirror 42 is disposed on the transparent conductive film 32.

### [(2) Multilayer Reflective Mirror]

A light reflection layer (DBR layer) that constitutes each of the first multilayer reflective mirror 41 and the second multilayer reflective mirror 42 is constituted from a semiconductor multilayer film or a dielectric multilayer film, for example. Examples of the dielectric material include oxides of Si, Mg, Al, Hf, Nb, Zr, Sc, Ta, Ga, Zn, Y, B, Ti, etc., nitrides (e.g., SiN_{X}, AlN_{X}, AlGaN_{X}, GaN_{X}, BN_{X}, etc.), fluorides, etc. Specifically, the dielectric material may be SiO_{X}, TiO_{X}, NbO_{X}, ZrO_{X}, TaO_{X}, ZnO_{X}, AlO_{X}, HfO_{X}, SiN_{X}, AlN_{X}, etc. The light reflection layer can be constituted by alternately laminating two or more kinds of dielectric films made of dielectric materials with different refractive indices, among these dielectric materials. Each of the first multilayer reflective mirror 41 and the second multilayer reflective mirror 42 is preferably a multilayer film of SiO_{X}/SiN_{Y}, SiO_{X}/TaO_{Y}, SiO_{X}/NbO_{Y}, SiO_{X}/ZrO_{Y}, SiO_{X}/AlN_{Y}, etc., for example.

The number of laminated layers of each of the first multilayer reflective mirror 41 and the second multilayer reflective mirror 42 may be 2 or more, preferably about 5 to 20. The thickness of each of the first multilayer reflective mirror 41 and the second multilayer reflective mirror 42 may be about 0.6 μm to 1.7 μm, for example. The optical reflectance of each of the first multilayer reflective mirror 41 and the second multilayer reflective mirror 42 is preferably 95% or more. The materials that constitute each dielectric film, film thickness, number of laminated layers, etc. are selected as appropriate in order to obtain a desired optical reflectance. The thickness of each dielectric film is adjusted as appropriate in accordance with the materials used, etc.

Each of the first multilayer reflective mirror 41 and the second multilayer reflective mirror 42 can be formed on the basis of a well-known method. Examples of the method include PVD methods such as a vacuum deposition method, a sputtering method, a reactive sputtering method, an ECR plasma sputtering method, a magnetron sputtering method, an ion beam assisted deposition method, an ion plating method, and a laser abrasion method; various kinds of CVD methods; application methods such as a spray method, a spin coat method, and a dip method, methods obtained by combining two or more kinds of these methods; and methods obtained by combining these methods with one or more kinds of overall or partial pre-treatment, irradiation with inert gas (such as Ar, He, and Xe) or plasma, irradiation with oxygen gas, ozone gas, or plasma, oxidation treatment (heat treatment), and light exposure treatment.

### [(3) Compound Semiconductor Substrate]

The compound semiconductor substrate 11 is conductive. The compound semiconductor substrate 11 may be a GaN substrate, a sapphire substrate, a GaAs substrate, an SiC substrate, an alumina substrate, a ZnS substrate, a ZnO substrate, an AlN substrate, an LiMgO substrate, an LiGaO₂ substrate, an MgAl₂O₄ substrate, an InP substrate, an Si substrate, or a substrate obtained by forming a foundation layer or a buffer layer on a surface of these substrates, for example. A GaN substrate with a low defect density is preferably used.

### [(4) Laminated Structure]

The laminated structure 20 is a structure in which the first compound semiconductor layer 21, the active layer 23, and the second compound semiconductor layer 22 are disposed in this order. The laminated structure 20 is disposed on the compound semiconductor substrate 11. Specifically, the laminated structure can be composed of an AlInGaN-based compound semiconductor. Here, more specifically, GaN, AlGaN, InGaN, and AlInGaN can be mentioned as the AlInGaN-based compound semiconductor. Further, these compound semiconductors may contain boron (B) atoms, thallium (Tl) atoms, arsenic (As) atoms, phosphorus (P) atoms, and antimony (Sb) atoms as desired.

Each of the first compound semiconductor layer 21 and the second compound semiconductor layer 22 may be a layer of a single structure, a multilayer structure, or a superlattice structure. Further, each of the first compound semiconductor layer 21 and the second compound semiconductor layer 22 may be a layer including a composition graded layer or a density graded layer.

The first compound semiconductor layer 21 can be constituted from a compound semiconductor of a first conductive type (e.g., n-type), and the second compound semiconductor layer 22 can be constituted from a compound semiconductor of a second conductive type (e.g., p-type) different from the first conductive type.

Examples of the method of forming each of the first compound semiconductor layer 21 and the second compound semiconductor layer 22 include, but are not limited to, a metal-organic chemical vapor deposition method (MOCVD method, MOVPE method), a molecular beam epitaxy method (MBE method), a hydride vapor-phase epitaxy method (HVPE method), an atomic layer deposition method (ALD method), a migration enhanced epitaxy method (MEE method), a plasma-assisted physical vapor deposition method (PPD method), etc.

The laminated structure 20 is provided with a current injected region 61A and a current non-injected region (current confinement region) 61B that surrounds the current injected region 61A. The current injected region 61A and the current non-injected region 61B can be formed on the basis of an ion implantation method. At least one kind of ion (i.e., one kind of ion or two or more kinds of ions) selected from the group consisting of boron, proton, phosphorous, arsenic, carbon, nitrogen, fluorine, oxygen, germanium, and silicon can be mentioned as the kind of ion to be implanted.

Alternatively, the current injected region 61A and the current non-injected region 61B can be formed on the second compound semiconductor layer 22 by an ashing process, a reactive etching (RIE) process, a plasma irradiation process, etc.

Examples of plasma particles include argon, oxygen, nitrogen, etc. Alternatively, the current injected region 61A and the current non-injected region 61B can also be formed by etching an insulating film formed on the second compound semiconductor layer 22. Examples of the material that constitutes the insulating film include SiO_{X}, SiN_{X}, AlO_{X}, ZrO_{X}, HfO_{X}, etc. Alternatively, in order to obtain the current confinement region, the second compound semiconductor layer 22, etc., may be etched by the RIE method, etc., to form a mesa structure. Alternatively, the current confinement region may be formed by partially oxidizing a part of the laminated second compound semiconductor layer 22 from a transverse direction.

Alternatively, these processes can be combined as appropriate. In some configuration examples, the current injected region 61A and the current non-injected region 61B may not be provided.

The laminated structure 20 is a structure in which the first compound semiconductor layer 21, the active layer 23, and the second compound semiconductor layer 22 are disposed in this order. The laminated structure 20 is disposed on the compound semiconductor substrate 11. Specifically, the laminated structure can be composed of an AlInGaN-based compound semiconductor. Here, more specifically, GaN, AlGaN, InGaN, and AlInGaN can be mentioned as the AlInGaN-based compound semiconductor. Further, these compound semiconductors may contain boron (B) atoms, thallium (Tl) atoms, arsenic (As) atoms, phosphorus (P) atoms, and antimony (Sb) atoms as desired.

Each of the first compound semiconductor layer 21 and the second compound semiconductor layer 22 may be a layer of a single structure, a multilayer structure, or a superlattice structure. Further, each of the first compound semiconductor layer 21 and the second compound semiconductor layer 22 may be a layer including a composition graded layer or a density graded layer.

The first compound semiconductor layer 21 can be constituted from a compound semiconductor of a first conductive type (e.g., n-type), and the second compound semiconductor layer 22 can be constituted from a compound semiconductor of a second conductive type (e.g., p-type) different from the first conductive type.

Examples of the method of forming each of the first compound semiconductor layer 21 and the second compound semiconductor layer 22 include, but are not limited to, a metal-organic chemical vapor deposition method (MOCVD method, MOVPE method), a molecular beam epitaxy method (MBE method), a hydride vapor-phase epitaxy method (HVPE method), an atomic layer deposition method (ALD method), a migration enhanced epitaxy method (MEE method), a plasma-assisted physical vapor deposition method (PPD method), etc.

The active layer 23 generates light. The Z-axis is the optical path axis of the light generated by the active layer 23. The active layer 23 preferably has a quantum well structure. The active layer 23 can have a single quantum well structure (SQW structure), a multi-quantum well structure (MQW structure), etc., for example. The active layer 23 having a quantum well structure has a structure in which at least one well layer and a barrier layer are laminated. Examples of the combination of compound semiconductors that constitute the well layer and the barrier layer include In_{y}Ga_{(1-y)}N and GaN, In_{y}Ga_{(1-y)}N and In_{z}Ga_{(1-z)}N [y>z], In_{y}Ga_{(1-y)}N and AlGaN, etc.

### [(5) Transparent Conductive Film]

The transparent conductive film 32 contains a transparent conductive material.

The transparent conductive material is a material having conductivity and optical transparency. Since the transparent conductive film 32 contains a transparent conductive material, the current can be spread in the transverse direction (in the in-plane direction of the second compound semiconductor layer 22). As a result, the current can be efficiently supplied to the current injected region.

Examples of the transparent conductive material include an indium-based transparent conductive material, a tin-based transparent conductive material, a zinc-based transparent conductive material, NiO, etc. Specific examples of the indium-based transparent conductive material include indium-tin oxides (including ITO, Sn-doped In₂O₃, crystalline ITO, and amorphous ITO), indium-zinc oxide (IZO), indium-gallium oxide (IGO), indium-doped gallium-zinc oxides (IGZO, In—GaZnO₄), IFO (F-doped In₂O₃), ITiO (Ti-doped In₂O₃), InSn, InSnZnO, etc. Specific examples of the tin-based transparent conductive material include tin oxide (SnO₂), ATO (Sb-doped SnO₂), FTO (F-doped SnO₂), etc. Specific examples of the zinc-based transparent conductive material include zinc oxides (including ZnO, Al-doped ZnO (AZO), and B-doped ZnO), gallium-doped zinc oxide (GZO), AlMgZnO (aluminum oxide and magnesium oxide-doped zinc oxide), etc.

Alternatively, the transparent conductive film 32 may be a transparent conductive film having gallium oxide, titanium oxide, niobium oxide, antimony oxide, nickel oxide, etc., as the base layer. Transparent conductive materials such as a spinel-type oxide and an oxide having a YbFe2O4 structure may be used as the transparent conductive film 32. Metals such as palladium (Pd), platinum (Pt), nickel (Ni), gold (Au), cobalt (Co), and rhodium (Rh) may be used as the transparent conductive film 32. The transparent conductive film 32 may be constituted from at least one kind of these materials.

The transparent conductive film 32 can be formed by a PVD method such as a vacuum deposition method and a sputtering method, for example. A semiconductor layer with a low resistance can also be used as a transparent electrode layer. In this case, specifically, an n-type GaN-based compound semiconductor layer can also be used. When a layer adjacent to the n-type GaN-based compound semiconductor layer is of a p-type, further, the two layers can be bonded via a tunnel junction to reduce the electric resistance at the interface.

The pad electrode 33 is configured to be electrically connected to an external electrode or circuit. It is desirable that the pad electrode 33 should have a single-layer constitution or a multilayer constitution including at least one kind of metal selected from the group consisting of Ti (titanium), aluminum (Al), Pt (platinum), Au (gold), Ni (nickel), and Pd (palladium). Alternatively, the pad electrode 33 may be a multilayer constitution of Ti/Pt/Au, a multilayer constitution of Ti/Au, a multilayer constitution of Ti/Pd/Au, a multilayer constitution of Ti/Pd/Au, a multilayer constitution of Ti/Ni/Au, a multilayer constitution of Ti/Ni/Au/Cr/Au, etc. In the multilayer constitution, a layer in front of “/” is positioned on the side closer to the active layer. The same applies to the description of the others.

In the related art, the electric resistance of the transparent conductive film 32 is higher than the electric resistance of the pad electrode 33, and therefore the characteristics of the transparent conductive film 32 may be varied by temporal variations when a current from the pad electrode 33 is input for a long time (e.g., about 100 hours).

It is conceivable to make the film thickness of the transparent conductive film 32 greater, in order to suppress variations in the characteristics of the transparent conductive film 32 due to the current input from the pad electrode 33. When the film thickness of the transparent conductive film 32 is made to be greater, however, there occurs a problem that the light generated by the active layer 23 is lost by the transparent conductive film 32 which absorbs light.

Thus, in the present technique, the film thickness of the transparent conductive film 32 disposed at a position in contact with the pad electrode 33 is greater than the film thickness of the transparent conductive film 32 disposed on the optical path of the light generated by the active layer 23. The drawing emphasizes that the film thickness of the transparent conductive film 32 disposed at a position in contact with the pad electrode 33 is greater.

Consequently, variations in the characteristics of the transparent conductive film 32 due to a current input from the pad electrode 33 are suppressed without degrading basic optical properties such as a threshold current and a slope efficiency. Consequently, the reliability of the transparent conductive film 32 is improved. As a result, a voltage rise, an open failure, and a current leakage failure, etc., are suppressed, for example, improving the reliability of the surface emitting laser 1. Further, the film thickness of the transparent conductive film 32 disposed on the optical path of the light generated by the active layer 23 is as in the related art (e.g., about 33 nm). Therefore, the problem that the light generated by the active layer 23 is lost is also resolved. These effects are also obtained in the other embodiments to be described later. Hence, repetitive description may be omitted in the other embodiments to be described later.

The film thickness of the transparent conductive film 32 disposed at a position in contact with the pad electrode 33 is preferably 1.5 times or more the film thickness of the transparent conductive film 32 disposed on the optical path of the light generated by the active layer 23. For example, when the film thickness of the transparent conductive film 32 disposed on the optical path of the light generated by the active layer 23 is 33 nm, the film thickness of the transparent conductive film 32 disposed at a position in contact with the pad electrode 33 may be about 50 nm.

Further, the film thickness of the transparent conductive film 32 disposed at a position in contact with the pad electrode 33 is more preferably twice or more the film thickness of the transparent conductive film 32 disposed on the optical path of the light generated by the active layer 23. For example, when the film thickness of the transparent conductive film 32 disposed on the optical path of the light generated by the active layer 23 is 33 nm, the film thickness of the transparent conductive film 32 disposed at a position in contact with the pad electrode 33 may be about 66 nm.

Consequently, it is possible to suppress variations in the characteristics of the transparent conductive film 32 due to the current input from the pad electrode 33. As a result, the reliability of the transparent conductive film 32 is improved. This effect is also obtained in the other embodiments to be described later. Thus, repetitive description may be omitted in the other embodiments.

The above description of the surface emitting laser 1 according to the first embodiment of the present technique can be applied to other embodiments of the present technique as long as there is no particular technical contradiction.

### 2. Second Embodiment of Present Technique (Example 2 of Surface Emitting Laser)

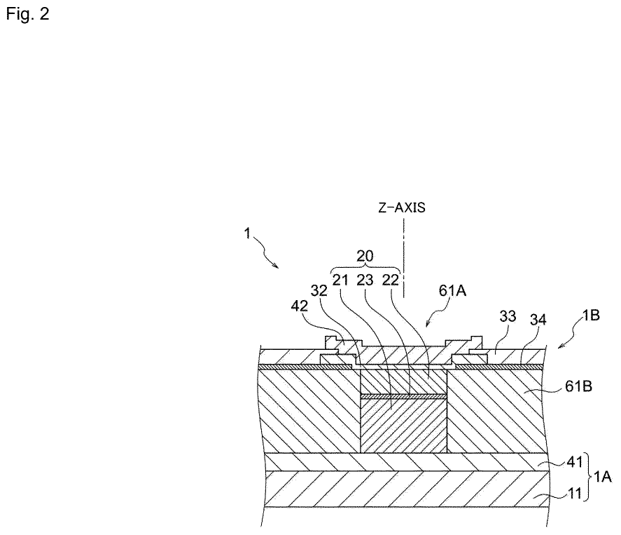

In the surface emitting laser 1 according to one embodiment of the present technique, at least one of the first multilayer reflective mirror 41 and the second multilayer reflective mirror 42 may contain a semiconductor material. This will be described with reference to FIG. 2. FIG. 2 is a cross-sectional view illustrating a configuration example of the surface emitting laser 1 according to one embodiment of the present technique. As illustrated in FIG. 2, the first multilayer reflective mirror 41 contains a semiconductor material, and the second multilayer reflective mirror 42 contains a dielectric material. Although not illustrated, the second multilayer reflective mirror 42 may contain a semiconductor material.

The above description of the surface emitting laser 1 according to the second embodiment of the present technique can be applied to other embodiments of the present technique as long as there is no particular technical contradiction.

### 3. Third Embodiment of Present Technique (Example 3 of Surface Emitting Laser)

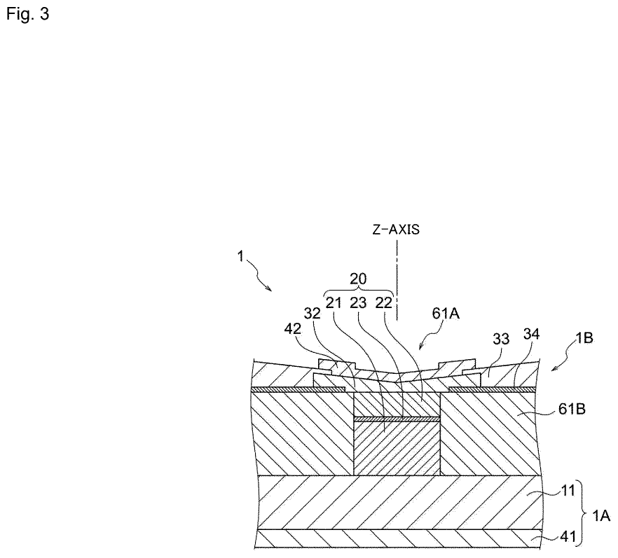

In the surface emitting laser 1 according to one embodiment of the present technique, the transparent conductive film 32 may be formed such that the film thickness of the transparent conductive film 32 becomes greater from the optical path of the light generated by the active layer 23 toward the pad electrode 33. This will be described with reference to FIG. 3. FIG. 3 is a cross-sectional view illustrating a configuration example of the surface emitting laser 1 according to one embodiment of the present technique. In the surface emitting laser 1 according to one embodiment of the present technique, as illustrated in FIG. 3, the transparent conductive film 32 is formed such that the film thickness of the transparent conductive film 32 becomes greater from the optical path of the light generated by the active layer 23 toward the pad electrode 33. In this embodiment, in particular, the transparent conductive film 32 is formed in a tapered shape. This tapered shape can be formed by using a technique such as grayscale exposure, for example.

While the tapered shape is composed of straight lines in this drawing, this shape is not limiting. For example, a part of the tapered shape may be curved.

The above description of the surface emitting laser 1 according to the third embodiment of the present technique can be applied to other embodiments of the present technique as long as there is no particular technical contradiction.

### 4. Fourth Embodiment of Present Technique (Example 4 of Surface Emitting Laser)

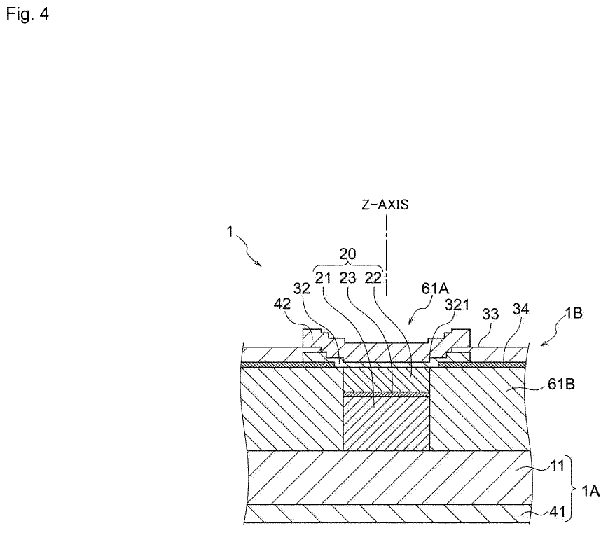

In the surface emitting laser 1 according to one embodiment of the present technique, the transparent conductive film 32 may be formed in a staircase shape including at least one step. This will be described with reference to FIG. 4. FIG. 4 is a cross-sectional view illustrating a configuration example of the surface emitting laser 1 according to one embodiment of the present technique. In the surface emitting laser 1 according to one embodiment of the present technique, as illustrated in FIG. 4, the transparent conductive film 32 is formed in a staircase shape including at least one step 321. The number of steps 321 is not specifically limited.

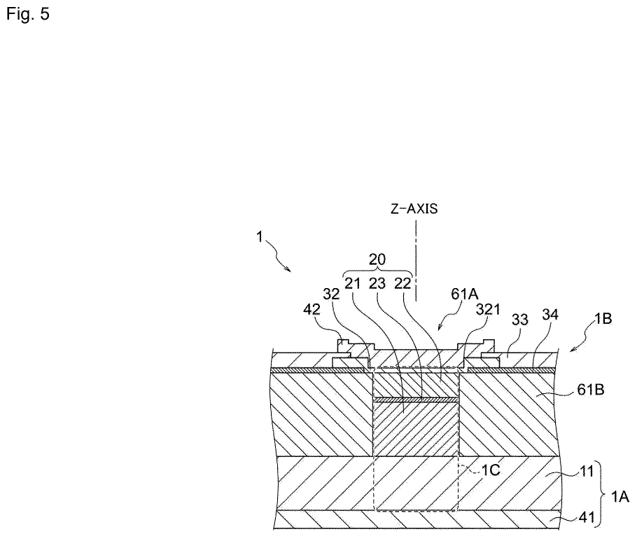

The steps 321 may be formed outside a resonator disposed between the first multilayer reflective mirror 41 and the second multilayer reflective mirror 42, or may be formed inside the resonator. This resonator will be described with reference to FIG. 5. FIG. 5 is a cross-sectional view illustrating a configuration example of the surface emitting laser 1 according to one embodiment of the present technique. A region disposed between the first multilayer reflective mirror 41 and the second multilayer reflective mirror 42, illustrated in FIG. 5, is a resonator 1C. In this embodiment, the steps 321 formed on the transparent conductive film 32 are formed outside the resonator 1C.

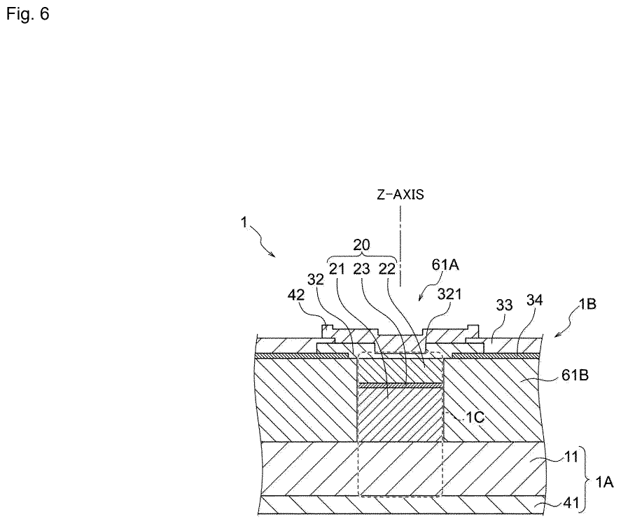

A configuration example of the surface emitting laser 1 according to another embodiment of the present technique will be described with reference to FIG. 6. FIG. 6 is a cross-sectional view illustrating a configuration example of the surface emitting laser 1 according to one embodiment of the present technique. As illustrated in FIG. 6, the steps 321 formed on the transparent conductive film 32 may be formed inside the resonator 1C.

In this embodiment, in addition, the steps 321 formed on the transparent conductive film 32 are formed inside the current injected region 61A. When the configuration of this embodiment is put in other words, the film thickness of the transparent conductive film 32 disposed in the vicinity of a position corresponding to the peak of the fundamental transverse mode of the light generated by the active layer 23 is smaller than the film thickness of the transparent conductive film 32 disposed in the vicinity of a position corresponding to the peak of the higher-order transverse mode of the light generated by the active layer 23. Consequently, it is possible to take out the fundamental transverse mode of the light generated by the active layer 23.

In this embodiment, further, modulation of the film thickness of the transparent conductive film 32 is transferred to the second multilayer reflective mirror 42, providing an anti-guide property as a property of spreading light. That is, in this embodiment, the NFP (Near Field Pattern) can be widened in angle to narrow the FFP (Far Field Patter) in angle. A greater effect is obtained in an embodiment in which the NFP tends to be particularly small.

The above description of the surface emitting laser 1 according to the fourth embodiment of the present technique can be applied to other embodiments of the present technique as long as there is no particular technical contradiction.

### 5. Fifth Embodiment of Present Technique (Example 5 of Surface Emitting Laser)

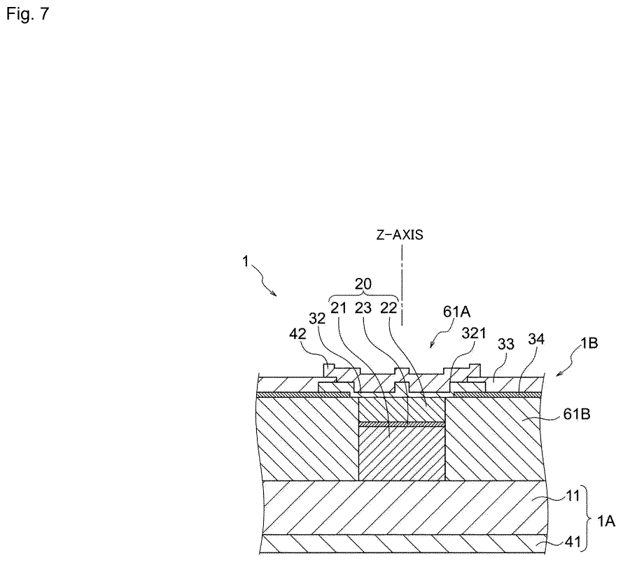

The surface emitting laser 1 according to the fourth embodiment of the present technique is a configuration example that allows taking out light in the fundamental transverse mode. On the other hand, the surface emitting laser 1 according to the fifth embodiment of the present technique may be a configuration example that allows taking out light in the higher-order transverse mode. This configuration example will be described with reference to FIG. 7. FIG. 7 is a cross-sectional view illustrating a configuration example of the surface emitting laser 1 according to one embodiment of the present technique. As illustrated in FIG. 7, the steps 321 formed on the transparent conductive film 32 are formed outside the current injected region 61A. The film thickness of the transparent conductive film 32 disposed on the optical path axis (Z-axis) of the light generated by the active layer 23 is greater than the film thickness of the transparent conductive film 32 disposed in regions other than that on the optical path. Consequently, it is possible to take out the higher-order transverse mode of the light generated by the active layer 23.

In this embodiment, further, the NFP (Near Field Pattern) can be narrowed in angle to widen the FFP (Far Field Patter) in angle.

The above description of the surface emitting laser 1 according to the fifth embodiment of the present technique can be applied to other embodiments of the present technique as long as there is no particular technical contradiction.

### 6. Sixth Embodiment of Present Technique (Example 6 of Surface Emitting Laser)

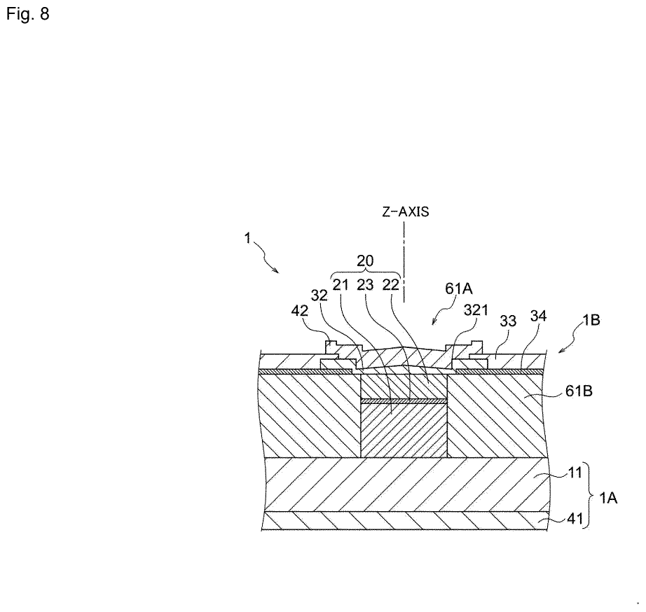

In the surface emitting laser 1 according to one embodiment of the present technique, the transparent conductive film 32 may be formed such that the film thickness of the transparent conductive film 32 becomes smaller from the optical path of the light generated by the active layer 23 toward the pad electrode 33. This will be described with reference to FIG. 8. FIG. 8 is a cross-sectional view illustrating a configuration example of the surface emitting laser 1 according to one embodiment of the present technique. In the surface emitting laser 1 according to one embodiment of the present technique, as illustrated in FIG. 8, the transparent conductive film 32 is formed such that the film thickness of the transparent conductive film 32 becomes smaller from the optical path of the light generated by the active layer 23 toward the pad electrode 33. In other words, the transparent conductive film 32 is formed in a tapered shape (tapered shape inverted from that according to the third embodiment). However, the film thickness of the transparent conductive film 32 disposed at a position in contact with the pad electrode 33 is greater than the film thickness of the transparent conductive film 32 disposed on the optical path of the light generated by the active layer 23. Consequently, the surface emitting laser 1 can emit a Bessel beam even without a part such as a lens. The surface emitting laser 1 according to the third embodiment in which the transparent conductive film 32 is formed in a tapered shape also can emit a Bessel beam.

The above description of the surface emitting laser 1 according to the sixth embodiment of the present technique can be applied to other embodiments of the present technique as long as there is no particular technical contradiction.

### 7. Seventh Embodiment of Present Technique (Example 7 of Surface Emitting Laser)

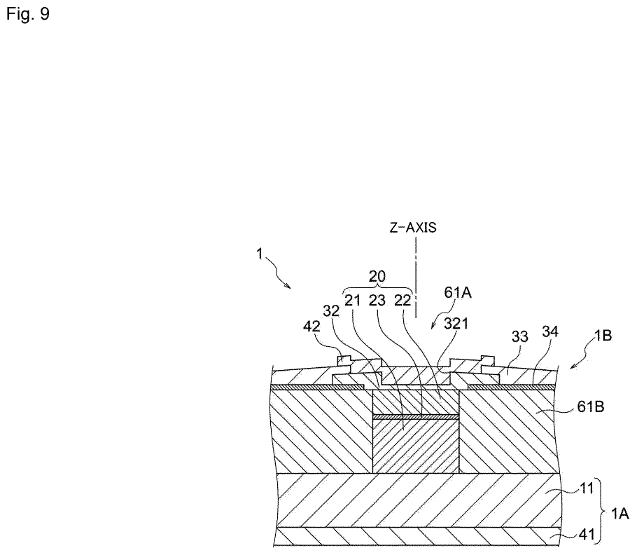

Another embodiment of the present technique will be described with reference to FIG. 9. FIG. 9 is a cross-sectional view illustrating a configuration example of the surface emitting laser 1 according to one embodiment of the present technique. As illustrated in FIG. 9, the steps 321 formed on the transparent conductive film 32 are formed inside the current injected region 61A. Consequently, it is possible to take out the fundamental transverse mode of the light generated by the active layer 23.

The transparent conductive film 32 outside the steps 321 is formed such that the film thickness of the transparent conductive film 32 becomes smaller from the optical path of the light generated by the active layer 23 toward the pad electrode 33. The film thickness of the transparent conductive film 32 disposed at a position in contact with the pad electrode 33 is greater than the film thickness of the transparent conductive film 32 disposed on the optical path of the light generated by the active layer 23.

The above description of the surface emitting laser 1 according to the seventh embodiment of the present technique can be applied to other embodiments of the present technique as long as there is no particular technical contradiction.

### 8. Eighth Embodiment of Present Technique (Example 8 of Surface Emitting Laser)

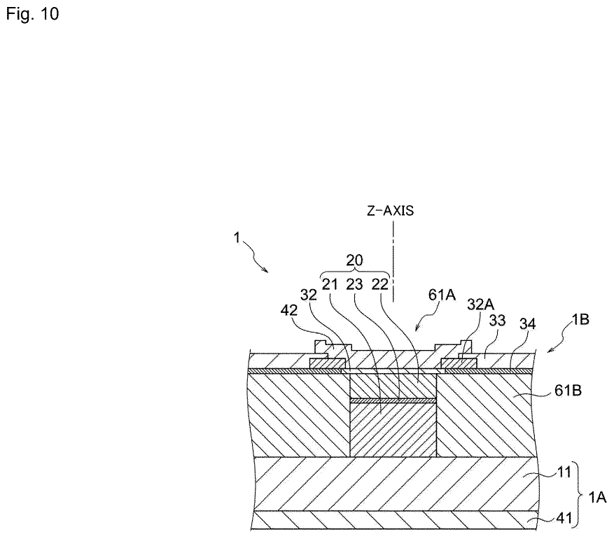

In the surface emitting laser 1 according to one embodiment of the present technique, the transparent conductive film 32 may include a plurality of film qualities. This will be described with reference to FIG. 10. FIG. 10 is a cross-sectional view illustrating a configuration example of the surface emitting laser 1 according to one embodiment of the present technique. As illustrated in FIG. 10, the transparent conductive film 32 includes a plurality of film qualities. In this configuration example, the film quality of a transparent conductive film 32A disposed at a position in contact with the pad electrode 33 is different from the film quality of the transparent conductive film 32 disposed on the optical path of the light generated by the active layer 23.

The respective film qualities of the transparent conductive film 32A disposed at a position in contact with the pad electrode 33 and the transparent conductive film 32 disposed on the optical path of the light generated by the active layer 23 are not specifically limited. Preferably, the transparent conductive film 32A disposed at a position in contact with the pad electrode 33 includes a film quality with a lower electric resistance than that of the transparent conductive film 32 disposed on the optical path of the light generated by the active layer 23.

In the related art, the electric resistance of the transparent conductive film 32 is higher than the electric resistance of the pad electrode 33, and therefore the characteristics of the transparent conductive film 32 may be varied by temporal variations when a current from the pad electrode 33 is input for a long time (e.g., about 100 hours). Therefore, the difference between the electric resistance of the transparent conductive film 32 disposed at a position in contact with the pad electrode 33 and the electric resistance of the pad electrode 33 is preferably small.

The above description of the surface emitting laser 1 according to the eighth embodiment of the present technique can be applied to other embodiments of the present technique as long as there is no particular technical contradiction.

### 9. Ninth Embodiment of Present Technique (Example 9 of Surface Emitting Laser)

The materials of members that constitute the surface emitting laser 1 according to one embodiment of the present technique are not specifically limited. It is known that the transparent conductive film 32 has a low absorption index for blue light of about 455 nm. Therefore, the resonator 1C disposed between the first multilayer reflective mirror 41 and the second multilayer reflective mirror 42 can contain a III-V compound.

While the compound contained in the resonator 1C is not specifically limited, the resonator 1C can contain one or more kinds of compounds selected from the group consisting of AlGaInN, AlGaInP, AlGaAs, and AlGaInNAs, for example.

The above description of the surface emitting laser 1 according to the ninth embodiment of the present technique can be applied to other embodiments of the present technique as long as there is no particular technical contradiction.

### 10. Tenth Embodiment of Present Technique (Example 10 of Surface Emitting Laser)

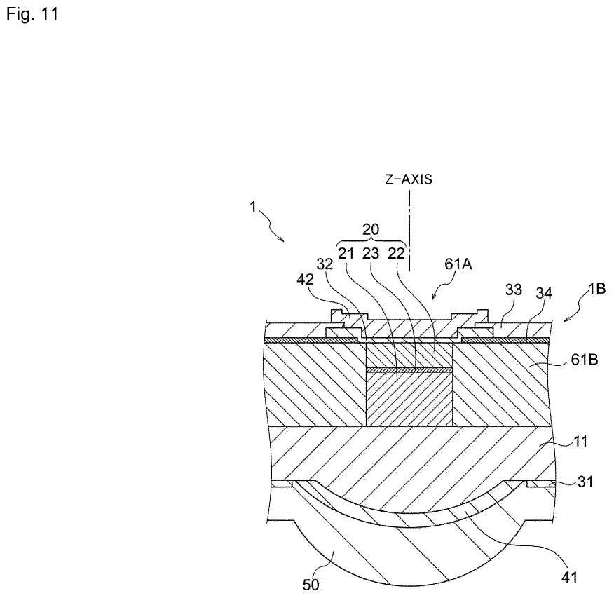

The surface emitting laser 1 according to one embodiment of the present technique may further include light converging-diverging means 50 for converging or diverging the light generated by the active layer 23. This will be described with reference to FIG. 11. FIG. 11 is a cross-sectional view illustrating a configuration example of the surface emitting laser 1 according to one embodiment of the present technique. As illustrated in FIG. 11, the surface emitting laser 1 further includes the light converging-diverging means 50 for converging or diverging the light generated by the active layer 23. An electrode 31 is formed around the first multilayer reflective mirror.

With the light converging-diverging means 50 provided, the light generated by the active layer 23 may be converged when the light passes through the light converging-diverging means 50, compared to that before passing through the light converging-diverging means 50. However, this is not limiting, and the light may be diverged, or may be parallelized, compared to that before passing through the light converging-diverging means 50.

The light converging-diverging means 50 can include a convex lens, a Fresnel lens, a hologram lens, etc., for example. In addition, the light converging-diverging means 50 can include a plasmonic element, a photonic crystal element, a metamaterial, a diffraction grating, etc., for example.

The material that constitutes the convex lens and the Fresnel lens is preferably an insulating layer containing a transparent material that transmits the light emitted from the active layer. Examples of the insulating layer containing a transparent material include silicon oxides (SiO_{X}), silicon nitrides (SiN_{Y}), silicon oxynitrides (SiO_{X}N_{Y}), tantalum oxide (Ta₂O₅), zirconium oxide (ZrO₂), aluminum oxide (Al₂O₃), aluminum nitride (AlN), titanium oxide (TiO₂), magnesium oxide (MgO), chromium oxides (CrO_{X}), vanadium oxides (VO), tantalum nitride (TaN), niobium oxides (NbO), etc.

The convex lens and the Fresnel lens can be formed by forming a resist material layer having the same cross-sectional shape as that of the convex lens and the Fresnel lens on the insulating layer containing a transparent material and etching back the insulating layer and the resist material layer.

The insulating layer containing a transparent material can be formed by various kinds of physical vapor deposition methods (PVD methods) and various kinds of chemical vapor deposition methods (CVD methods), depending on the material used. Alternatively, the insulating layer can be formed by applying a photosensitive resin material and exposing the photosensitive resin material to light, or can be formed by forming a transparent resin material into a lens shape on the basis of a nanoprint method.

The position at which the light converging-diverging means 50 is disposed is not specifically limited. Although not illustrated, the light converging-diverging means 50 may be disposed on the side opposite to the side where the light converging-diverging means 50 illustrated in FIG. 11 is disposed.

Besides, techniques disclosed in WO 2019/017044, etc., can be used as the technique related to the light converging-diverging means 50, for example.

The above description of the surface emitting laser 1 according to the tenth embodiment of the present technique can be applied to other embodiments of the present technique as long as there is no particular technical contradiction.

### 11. Eleventh Embodiment of Present Technique (Example 11 of Surface Emitting Laser)

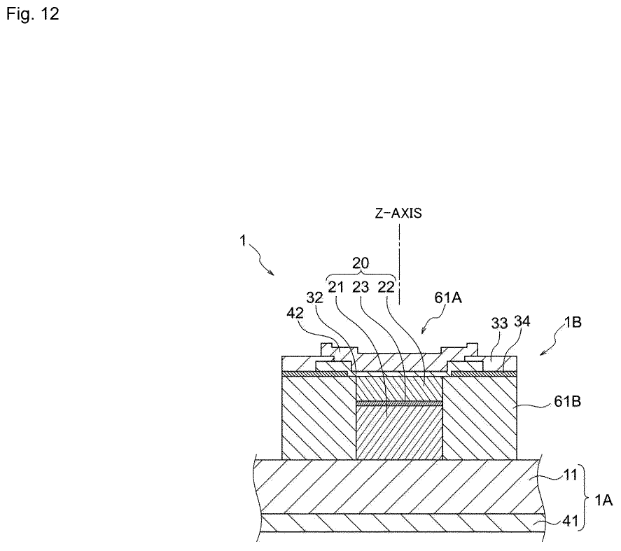

The surface emitting laser 1 according to one embodiment of the present technique may be constituted as a mesa-type structure. This will be explained with reference to FIG. 12. FIG. 12 is a cross-sectional view illustrating a configuration example of the surface emitting laser 1 according to one embodiment of the present technique. As illustrated in FIG. 12, the surface emitting laser 1 is constituted as a mesa-type structure. Consequently, a current can be confined inside the surface emitting laser 1 even without the current confinement region 61B.

Although not illustrated, light can be confined inside the surface emitting laser 1 by disposing a dielectric material with a low refractive index outside the surface emitting laser 1.

The above description of the surface emitting laser 1 according to the eleventh embodiment of the present technique can be applied to other embodiments of the present technique as long as there is no particular technical contradiction.

### 12. Twelfth Embodiment of Present Technique (Example of Surface Emitting Laser Array)

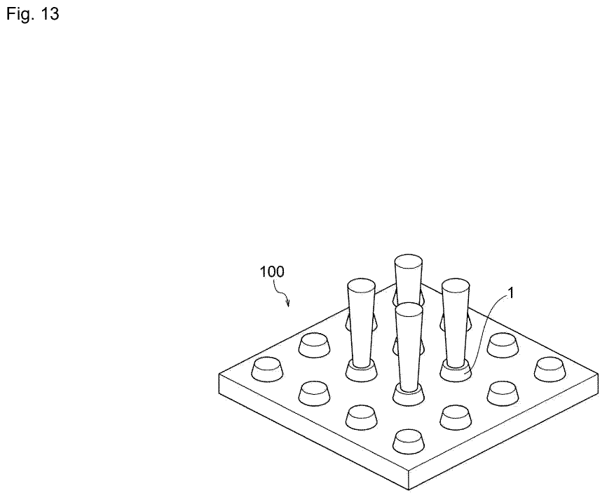

The present technique provides a surface emitting laser array in which the surface emitting lasers 1 according to the above first to twelfth embodiments are arranged multi-dimensionally. This will be described with reference to FIG. 13. FIG. 13 is a perspective view illustrating a configuration example of a surface emitting laser array 100 according to one embodiment of the present technique. As illustrated in FIG. 13, the surface emitting lasers 1 are arranged multi-dimensionally in the surface emitting laser array 100.

The plurality of surface emitting lasers 1 arranged multi-dimensionally in the surface emitting laser array 100 may emit light at different wavelengths. The surface emitting lasers 1 can emit blue light, green light, red light, etc., for example. The surface emitting lasers 1 may be mounted on a single substrate, for example.

While the surface emitting lasers 1 are arranged two-dimensionally in this configuration example, the surface emitting lasers 1 may be arranged three-dimensionally, for example.

The above description of the surface emitting laser array 100 according to the twelfth embodiment of the present technique can be applied to other embodiments of the present technique as long as there is no particular technical contradiction.

### 13. Thirteenth Embodiment of Present Technique (Example of Electronic Device)

The electronic device according to one embodiment of the present technique is an electronic device provided with the surface emitting laser 1 according to any one of the first to twelfth embodiments of the present technique. The power consumption of the electronic device is reduced since the surface emitting laser 1 is provided.

The surface emitting laser 1 according to one embodiment of the present technique is applicable to an electronic device that emits laser light, such as a TOF (Time Of Flight) sensor, for example. When applied to a TOF sensor, the electronic device is applicable to a distance image sensor using a direct TOF measuring method or a distance image sensor using an indirect TOF measuring method, for example. In the distance image sensor using the direct TOF measuring method, the timing of arrival of photons is determined in a direct time domain in each pixel. Thus, an optical pulse with a short pulse width is transmitted from a light source, and an electric pulse is generated by a light receiving element. The present technique is applicable to the light source at this time. In the indirect TOF method, a time of flight of light is measured using a semiconductor element structure in which the detection and accumulation amount of a carrier generated by light are changed depending upon the timing of arrival of light. The present technique is also applicable to the light source when such an indirect TFO method is used.

The surface emitting laser 1 according to one embodiment of the present technique may be realized as a light source of the TOF sensor installed in a moving body (e.g., an automobile, an electric vehicle, a hybrid electric vehicle, a motorcycle, a bicycle, a personal mobility device, an airplane, a drone, a ship, a robot, etc.).

The surface emitting laser 1 according to one embodiment of the present technique may be realized as a light source of a device that forms or displays an image using laser light (e.g., a laser printer, a laser copier, a projector, a head-mounted display, a head-up display, etc.).

The above description of the electronic device according to the thirteenth embodiment of the present technique can be applied to other embodiments of the present technique as long as there is no particular technical contradiction.

### 14. Fourteenth Embodiment of Present Technique (Example of Method of Producing Surface Emitting Laser)

The present technique provides a method of producing a surface emitting laser including: a first structure including a first multilayer reflective mirror; an active layer; and a second structure including a transparent conductive film, a pad electrode, and a second multilayer reflective mirror, the first structure, the active layer, and the second structure being disposed in this order, in which the method includes forming the transparent conductive film separately in a plurality of steps such that a film thickness of the transparent conductive film disposed at a position in contact with the pad electrode is greater than a film thickness of the transparent conductive film disposed on an optical path of light generated by the active layer.

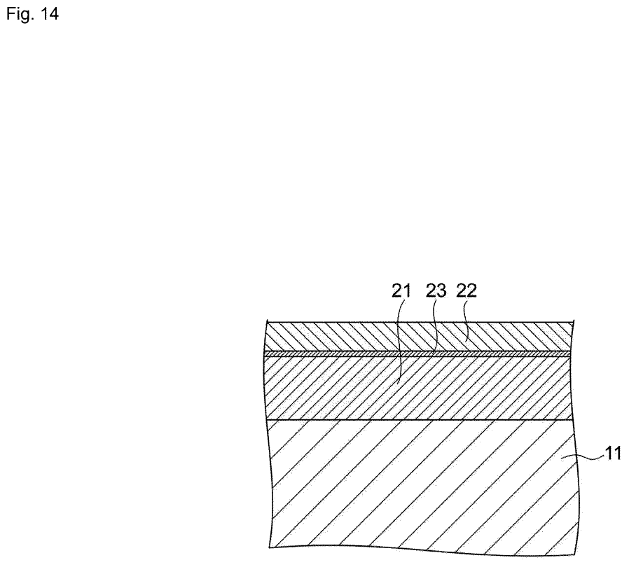

A method of producing a surface emitting laser according to one embodiment of the present technique will be described with reference to FIGS. 14 to 21. FIGS. 14 to 21 are each a cross-sectional view illustrating a configuration example of the surface emitting laser 1 according to one embodiment of the present technique.

First, as illustrated in FIG. 14, a first compound semiconductor layer 21, an active layer 23, and a second compound semiconductor layer 22 are laminated in this order on a compound semiconductor substrate 11 with a thickness of about 0.4 mm. An epitaxial growth method based on a well-known MOCVD method, etc., can be used, for example.

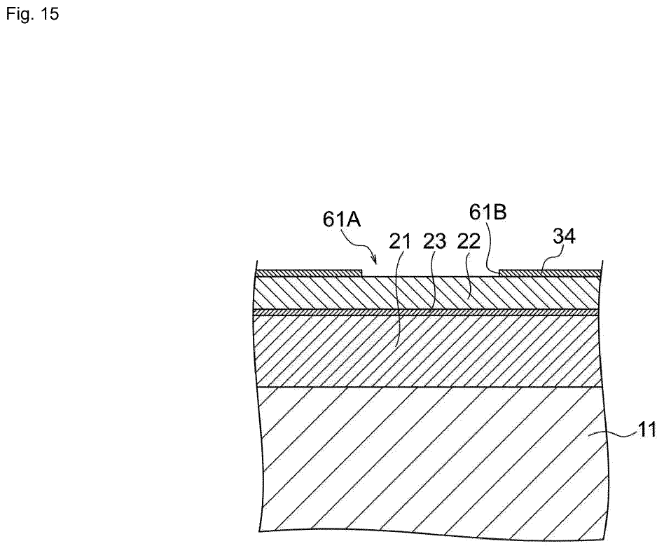

Next, as illustrated in FIG. 15, an insulating film (current confinement film) 34 is formed on the second compound semiconductor layer 22. Consequently, a current confinement region (current injected region 61A and current non-injected region 61B) is prescribed. A film forming method such as a CVD method, a sputtering method, and a vacuum deposition method and a patterning method such as a wet etching method and a dry etching method can be combined, for example.

In order to obtain a current confinement region, an insulating film (current confinement layer) made of an insulating material (e.g., SiO_{X}, SiN_{X}, AlO_{X}, ZrO_{X}, HfO_{X}, etc.) may be formed between the transparent conductive film 32 and the second compound semiconductor layer 22. A mesa structure may be formed by etching the second compound semiconductor layer 22 by an RIE method, etc. A current confinement region may be formed by partially oxidizing a part of the laminated second compound semiconductor layer 22 from a transverse direction. A region with reduced conductivity may be formed by ion implantation of impurities into the second compound semiconductor layer 22. These methods may be combined as appropriate. However, it is necessary that the transparent conductive film 32 should be electrically connected to a portion of the second compound semiconductor layer 22 through which a current flows as a result of current confinement.

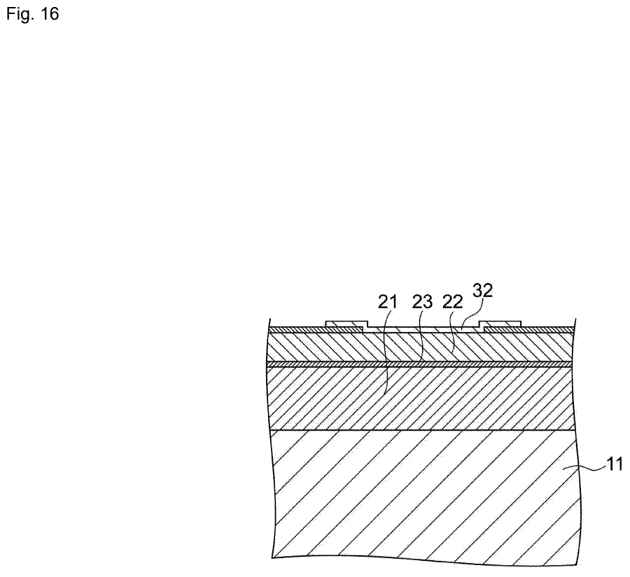

Next, as illustrated in FIG. 16, a transparent conductive film 32 is formed on the second compound semiconductor layer 22. A lift off method, etc., can be used after patterning a resist, for example.

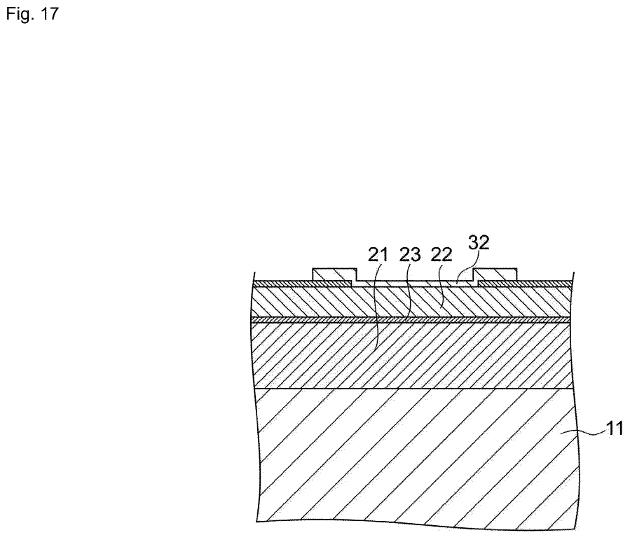

Next, as illustrated in FIG. 17, a transparent conductive film 32 is further formed at a position to be in contact with the pad electrode 33. Consequently, the film thickness of the transparent conductive film 32 disposed at a position to be in contact with the pad electrode 33 is made to be greater than the film thickness of the transparent conductive film 32 disposed on the optical path of the light generated by the active layer 23.

In this manner, the transparent conductive film 32 is formed separately in a plurality of steps. While the transparent conductive film 32 is formed separately in two steps in this example, the transparent conductive film 32 may be formed separately in three or more steps.

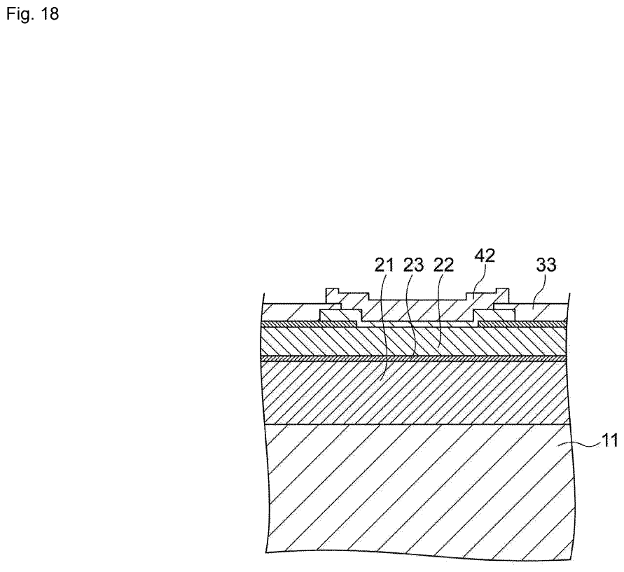

Next, as illustrated in FIG. 18, a pad electrode 33 is formed on an end portion of the transparent conductive film 32 and the insulating film 34. A second multilayer reflective mirror 42 is formed on the transparent conductive film 32. A film forming method such as a CVD method, a sputtering method, and a vacuum deposition method and a patterning method such as a wet etching method and a dry etching method can be combined, for example.

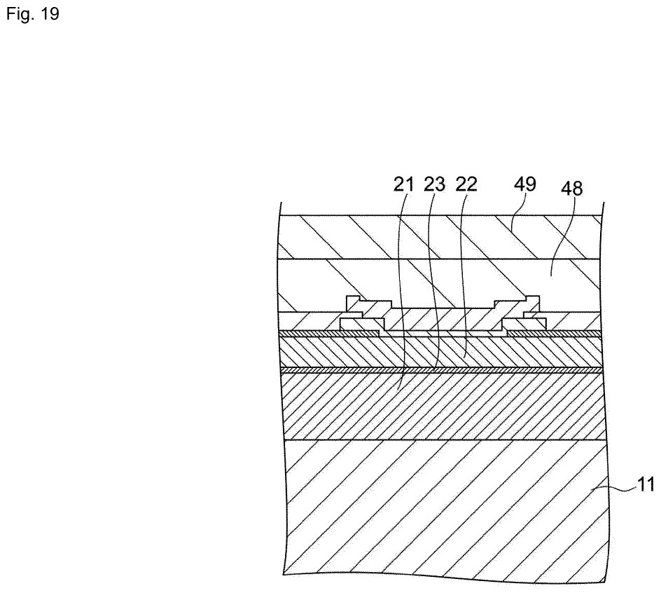

Next, as illustrated in FIG. 19, the second multilayer reflective mirror 42 is fixed to a support substrate 49 via a bonding layer 48. The bonding layer 48 may be an adhesive, for example. The support substrate 49 may be constituted of an insulating substrate made of AlN, etc., a semiconductor substrate made of Si, SiC, Ge, etc., a metal substrate, an alloy substrate, etc., for example. The support substrate 49 is preferably a conductive substrate. The support substrate 49 is preferably a metal substrate or an alloy substrate from the viewpoint of mechanical properties, elastic deformation, plastic deformability, heat radiation, etc. The support substrate 49 can have a thickness of 0.05 mm to 1 mm, by way of example.

The method of fixation to the support substrate 49 can be a known method such as a solder bonding method, a room-temperature bonding method, a bonding method using an adhesive tape, a bonding method using wax bonding, a method using an adhesive, etc., for example. From the viewpoint of securing conductivity, the solder bonding method or the room-temperature bonding method is preferably used. When a silicon semiconductor substrate which is a conductive substrate is used as the support substrate 49, for example, a method that enables bonding at a low temperature of 400 degrees or lower is preferably used, in order to suppress warpage due to the difference in thermal expansion coefficient. When a GaN substrate is used as the support substrate 49, the bonding temperature may be 400 degrees or higher.

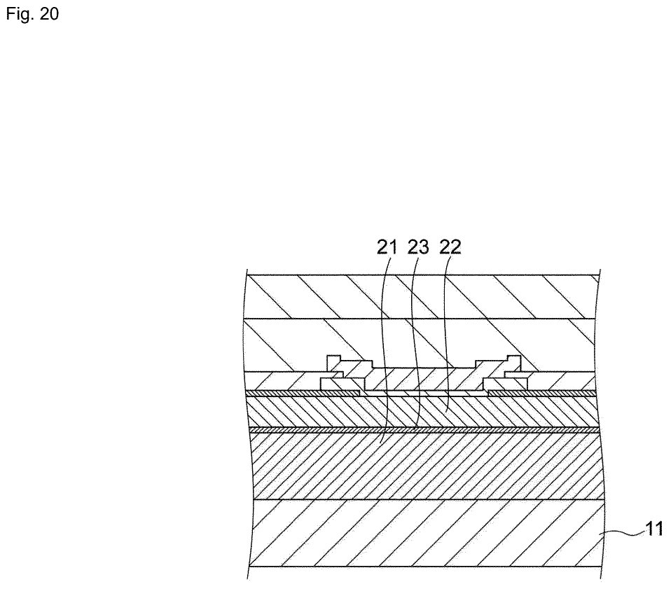

Next, as illustrated in FIG. 20, the compound semiconductor substrate 11 is thinned using a mechanical polishing method, a CMP method, etc. After that, the bonding layer 48 and the support substrate 49 may be removed, or the bonding layer 48 and the support substrate 49 may be left.

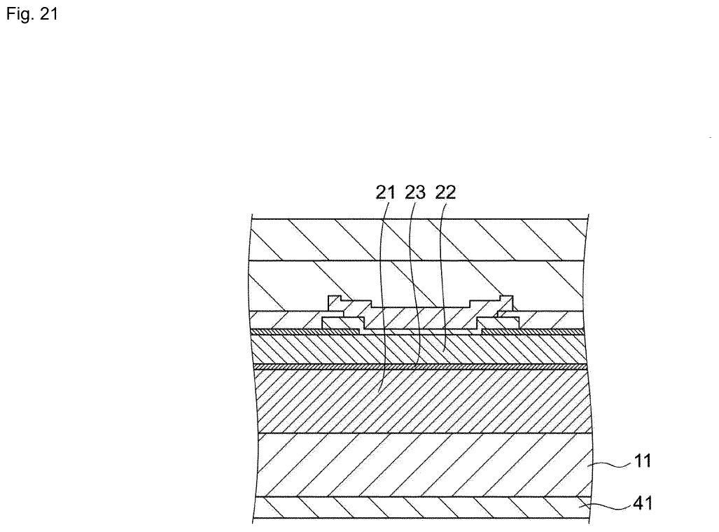

Next, as illustrated in FIG. 21, a first multilayer reflective mirror 41 is formed on the compound semiconductor substrate 11. A film forming method such as a CVD method, a sputtering method, and a vacuum deposition method and a patterning method such as a wet etching method and a dry etching method can be combined, for example.

Finally, the support substrate 49 and the bonding layer 48 are removed. Consequently, the configuration example illustrated in FIG. 1 is obtained.

The above description of the method of producing a surface emitting laser according to the fourteenth embodiment of the present technique can be applied to other embodiments of the present technique as long as there is no particular technical contradiction.

Embodiments according to the present technique are not limited to each of the above-described embodiments, and a variety of modifications are possible within the scope of the gist of the present technique. The specific numerical values, shapes, materials (including compositions), etc., described in relation to each of the embodiments are exemplary, and are not limiting.

The present technique can be configured as follows.

[1]

A surface emitting laser including:
a first structure including a first multilayer reflective mirror;
an active layer; and
a second structure including a transparent conductive film, a pad electrode, and a second multilayer reflective mirror, the first structure, the active layer, and the second structure being disposed in this order, in which
a film thickness of the transparent conductive film disposed at a position in contact with the pad electrode is greater than a film thickness of the transparent conductive film disposed on an optical path of light generated by the active layer.
   [2]

The surface emitting laser according to [1], in which the film thickness of the transparent conductive film disposed at a position in contact with the pad electrode is 1.5 times or more the film thickness of the transparent conductive film disposed on the optical path of the light generated by the active layer.

[3]

The surface emitting laser according to [1] or [2], in which
the film thickness of the transparent conductive film disposed at a position in contact with the pad electrode is twice or more the film thickness of the transparent conductive film disposed on the optical path of the light generated by the active layer.
   [4]

The surface emitting laser according to any one of [1] to [3], in which
the transparent conductive film is formed such that the film thickness of the transparent conductive film becomes greater from the optical path of the light generated by the active layer toward the pad electrode.
   [5]

The surface emitting laser according to [4], in which
the transparent conductive film is formed in a tapered shape.
   [6]

The surface emitting laser according to [4] or [5], in which
the transparent conductive film is formed in a staircase shape including at least one step.
   [7]

The surface emitting laser according to [6], in which
the step is formed outside a resonator disposed between the first multilayer reflective mirror and the second multilayer reflective mirror.
   [8]

The surface emitting laser according to [6] or [7], in which
the step is formed inside a resonator disposed between the first multilayer reflective mirror and the second multilayer reflective mirror.
   [9]

The surface emitting laser according to any one of [6] to [8], in which
the step is formed inside a current injected region.
   [10]

The surface emitting laser according to any one of [6] to [9], in which:
the step is formed outside a current injected region; and the film thickness of the transparent conductive film disposed on an optical path axis of the light generated by the active layer is greater than the film thickness of the transparent conductive film disposed in regions other than that on the optical path.
   [11]

The surface emitting laser according to any one of [1] to [10], in which
the transparent conductive film is formed such that the film thickness of the transparent conductive film becomes smaller from the optical path of the light generated by the active layer toward the pad electrode.
   [12]

The surface emitting laser according to [11], in which
the transparent conductive film is formed in a tapered shape.
   [13]

The surface emitting laser according to any one of [1] to [12], in which
the transparent conductive film includes a plurality of film qualities.
   [14]

The surface emitting laser according to [13], in which
the transparent conductive film disposed at a position in contact with the pad electrode includes a film quality with a lower electric resistance than that of the transparent conductive film disposed on the optical path of the light generated by the active layer.
   [15]

The surface emitting laser according to any one of [1] to [14], in which
a resonator disposed between the first multilayer reflective mirror and the second multilayer reflective mirror contains a III-V compound.
   [16]

The surface emitting laser according to [15], in which
the resonator contains one or more kinds of compounds selected from the group consisting of AlGaInN, AlGaJnP, AlGaAs, and AlGaJnNAs.
   [17]

The surface emitting laser according to any one of [1] to [16], further including light converging-diverging means for converging or diverging the light generated by the active layer.

[18]

The surface emitting laser according to any one of [1] to [17], in which
the surface emitting laser is constituted as a mesa-type structure.
   [19]

The surface emitting laser according to any one of [1] to [18], in which
the first multilayer reflective mirror and the second multilayer reflective mirror contains a dielectric material.
   [20]

The surface emitting laser according to any one of [1] to [19], in which
at least one of the first multilayer reflective mirror and the second multilayer reflective mirror contains a semiconductor material.
   [21]

The surface emitting laser according to [1] to [20], in which:
the first multilayer reflective mirror and the second multilayer reflective mirror contains a dielectric material; and
the surface emitting laser further includes light converging-diverging means for converging or diverging the light generated by the active layer.
   [22]

A surface emitting laser array including the surface emitting lasers according to any one of [1] to [21] arranged multi-dimensionally.

[23]

An electronic device including the surface emitting laser according to any one of [1] to [21].

[24]

A method of producing a surface emitting laser including: a first structure including a first multilayer reflective mirror; an active layer; and a second structure including a transparent conductive film, a pad electrode, and a second multilayer reflective mirror, the first structure, the active layer, and the second structure being disposed in this order, in which the method includes forming the transparent conductive film separately in a plurality of steps such that a film thickness of the transparent conductive film disposed at a position in contact with the pad electrode is greater than a film thickness of the transparent conductive film disposed on an optical path of light generated by the active layer.

### REFERENCE SIGNS LIST

1 Surface emitting laser
1A First structure
1B Second structure
1C Resonator
11 Compound semiconductor substrate
Laminated structure
21 First compound semiconductor layer
22 Second compound semiconductor layer
23 Active layer
31 Electrode
32 Transparent conductive film
321 Step
33 Pad electrode
34 Insulating film (current confinement region)
41 First multilayer reflective mirror
42 Second multilayer reflective mirror
48 Bonding layer
49 Support substrate
50 Light converging-diverging means
61A Current injected region
61B Current non-injected region (current confinement region)
100 Surface emitting laser array

1. A surface emitting laser comprising:
a first structure including a first multilayer reflective mirror;
an active layer; and
a second structure including a transparent conductive film, a pad electrode, and a second multilayer reflective mirror, the first structure, the active layer, and the second structure being disposed in this order, wherein
a film thickness of the transparent conductive film disposed at a position in contact with the pad electrode is greater than a film thickness of the transparent conductive film disposed on an optical path of light generated by the active layer.

2. The surface emitting laser according to claim 1, wherein
the film thickness of the transparent conductive film disposed at a position in contact with the pad electrode is 1.5 times or more the film thickness of the transparent conductive film disposed on the optical path of the light generated by the active layer.

3. The surface emitting laser according to claim 1, wherein
the film thickness of the transparent conductive film disposed at a position in contact with the pad electrode is twice or more the film thickness of the transparent conductive film disposed on the optical path of the light generated by the active layer.

4. The surface emitting laser according to claim 1, wherein
the transparent conductive film is formed such that the film thickness of the transparent conductive film becomes greater from the optical path of the light generated by the active layer toward the pad electrode.

5. The surface emitting laser according to claim 4, wherein
the transparent conductive film is formed in a tapered shape.

6. The surface emitting laser according to claim 4, wherein
the transparent conductive film is formed in a staircase shape including at least one step.

7. The surface emitting laser according to claim 6, wherein
the step is formed outside a resonator disposed between the first multilayer reflective mirror and the second multilayer reflective mirror.

8. The surface emitting laser according to claim 6, wherein
the step is formed inside a resonator disposed between the first multilayer reflective mirror and the second multilayer reflective mirror.

9. The surface emitting laser according to claim 6, wherein
the step is formed inside a current injected region.

10. The surface emitting laser according to claim 6, wherein
the step is formed outside a current injected region; and
the film thickness of the transparent conductive film disposed on an optical path axis of the light generated by the active layer is greater than the film thickness of the transparent conductive film disposed in regions other than that on the optical path.

11. The surface emitting laser according to claim 1, wherein
the transparent conductive film is formed such that the film thickness of the transparent conductive film becomes smaller from the optical path of the light generated by the active layer toward the pad electrode.

12. The surface emitting laser according to claim 11, wherein
the transparent conductive film is formed in a tapered shape.

13. The surface emitting laser according to claim 1, wherein
the transparent conductive film includes a plurality of film qualities.

14. The surface emitting laser according to claim 13, wherein
the transparent conductive film disposed at a position in contact with the pad electrode includes a film quality with a lower electric resistance than that of the transparent conductive film disposed on the optical path of the light generated by the active layer.

15. The surface emitting laser according to claim 1, wherein
a resonator disposed between the first multilayer reflective mirror and the second multilayer reflective mirror contains a III-V compound.

16. The surface emitting laser according to claim 15, wherein
the resonator contains one or more kinds of compounds selected from the group consisting of AlGaInN, AlGaInP, AlGaAs, and AlGaInNAs.

17. The surface emitting laser according to claim 1, further comprising
light converging-diverging means for converging or diverging the light generated by the active layer.

18. The surface emitting laser according to claim 1, wherein
the surface emitting laser is constituted as a mesa-type structure.

19. A surface emitting laser array comprising the surface emitting lasers according to claim 1 arranged multi-dimensionally.

20. An electronic device comprising the surface emitting laser according to claim 1.
